(19) United States
(12) Patent Application Publication
(10) Pub. No.: US 2025/0246670 A1
(43) Pub. Date: Jul. 31, 2025

(54) SECONDARY BATTERY INSPECTION DEVICE AND SECONDARY BATTERY INSPECTION METHOD

(71) Applicant: SK On Co., Ltd., Seoul (KR)

(72) Inventors: Hwan Cheol YOU, Daejeon (KR); Eun Jeong KIM, Daejeon (KR); Seo Jeong PARK, Daejeon (KR); Chang Hyun HWANG, Daejeon (KR); Hyung Joon KIM, Daejeon (KR)

(21) Appl. No.: 19/007,070

(22) Filed: Dec. 31, 2024

(30) Foreign Application Priority Data
Jan. 29, 2024 (KR) 10-2024-0013475
May 24, 2024 (KR) 10-2024-0067920

(51) Int. Cl. H01M 10/04; G01R 31/364; G01R 31/385; G01R 31/389; G01R 31/52; H01M 10/42

(52) U.S. Cl. CPC H01M 10/0468; G01R 31/364; G01R 31/385; G01R 31/389; G01R 31/52; H01M 10/4285

(57) ABSTRACT

Proposed are a secondary battery inspection device and a secondary battery inspection method. The secondary battery inspection device includes a plate provided such that the plate is capable of being slidably moved, a movement guide part guiding a movement of the plate, and a pressing part configured to press one side portion of the plate.

### CROSS REFERENCE TO RELATED APPLICATION

The present application claims priority to Korean Patent Application No. 10-2024-0013475, filed Jan. 29, 2024 and Korean Patent Application No. 10-2024-0067920, filed May 24, 2024, the entire contents of which is incorporated herein for all purposes by this reference.

### BACKGROUND

### Technical Field

The present disclosure relates to a secondary battery inspection device and a secondary battery inspection method.

### Description of the Related Art

In recent years, demands of portable electronic products such as a laptop computer, a video camera, and a portable telephone have increased, and an electric vehicle, a storage battery for energy storage, a robot, a satellite and the like have been developed. In addition, as an eco-friendly energy source, a secondary battery used as a driving power source requires significant research and development to meet the rapidly increasing demand.

For example, such a secondary battery may include a nickel-cadmium battery, a nickel-hydrogen battery, a nickel-zinc battery, a lithium secondary battery, and so on.

Among them, the lithium secondary batteries are widely used in the field of high-tech electronic devices because they have advantages, for example, they hardly exhibit memory effects in comparison with nickel-based secondary batteries and thus are freely charged and discharged, and they have a very low self-discharge rate, high operating voltage, and high energy density per unit weight.

Generally, a lithium secondary battery is configured such that a stack or wound structure of an electrode assembly formed of a positive electrode, a negative electrode, and a separator interposed between the positive electrode and the negative electrode is embedded in a metal can or a casing of a laminate sheet into which an electrolyte solution is then injected or poured.

### Document of Related Art

(Patent Document 1) KR 10-2022-0118250 A

### SUMMARY

According to an aspect of the present disclosure, a secondary battery inspection device for inspecting a defect of a separator of a secondary battery and a secondary battery inspection method may be provided.

According to another aspect of the present disclosure, a secondary battery inspection device and a secondary battery inspection method that are capable of being widely applied in green technology fields such as eco-friendly electric vehicles, hybrid vehicles, battery charging stations, and other fields using a battery, such as the solar photovoltaic power generation field, the wind power generation field, and so on may be provided.

According to an embodiment of the present disclosure, there is provided a secondary battery inspection device including: a plate provided such that the plate is capable of being slidably moved; a movement guide part guiding a movement of the plate; and a pressing part configured to press one side portion of the plate.

The plate may be configured to press a secondary battery, and the secondary battery inspection device may further include a pad part provided between the plate and the secondary battery.

The pad part may include a partial pressing part which has a convex shape and which is provided on both border portions of the pad part.

The pad part may include a partial pressing part which has a convex shape and which is provided on a position corresponding to a border portion of the secondary battery where a tab part extends.

The partial pressing part may be formed in a flat shape, a rounded shape, or a wavy shape so that the partial pressing part is capable of being in close contact with the border portion of the secondary battery.

The pad part may be provided with an insertion space part that is bent, and the plate may be fitted and coupled to the insertion space part.

According to an embodiment of the present disclosure, the secondary battery inspection device may further include an interleaving sheet which is configured to surround the pad part and in which the secondary battery is seated.

The interleaving sheet may be provided with a plurality of interleaving bending parts continuously bent, the pad part may be fitted and coupled to any one interleaving bending part, and the secondary battery may be seated in the other interleaving bending part.

According to an embodiment of the present disclosure, the secondary battery inspection device may further include a probe provided on opposite side portions of the plate and electrically connected to a tab part of the secondary battery.

According to an embodiment of the present disclosure, the secondary battery inspection device may further include an electrode guide part guiding a position of the secondary battery.

The electrode guide part may be provided on a lower portion of the probe, and may support the secondary battery from the lower portion of the probe.

The electrode guide part may include: a guide block which is fixed to the lower portion of the probe and which extends vertically from the lower portion of the probe toward the secondary battery; and a support block that extends vertically upward from an end portion of the guide block.

According to an embodiment of the present disclosure, there is provided a secondary battery inspection method including: a supplying process in which a secondary battery is supplied; a pressing process in which the secondary battery is pressed; and a voltage measurement process in which a voltage in the secondary battery is measured.

In the pressing process, the secondary battery may be partially pressed.

In the pressing process, an extension portion of a tab part in the secondary battery may be partially pressed.

The features and advantages of the present disclosure will be more clearly understood from the following detailed description based on the accompanying drawings.

The terms and words used in the present specification and claims should not be interpreted as being limited to typical meanings and dictionary definitions, but should be interpreted as having meanings and concepts relevant to the technical scope of the present disclosure based on the rule according to which an inventor can appropriately define the concept of the term to describe most appropriately the best method he or she knows for carrying out the present disclosure.

According to an embodiment of the present disclosure, a defect in a secondary battery is capable of being detected.

In addition, a short circuit inside a secondary battery is capable of being prevented from occurring.

In addition, an open circuit voltage is capable of being detected without a separate voltage supply to a secondary battery.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view schematically illustrating a secondary battery inspection device according to a first embodiment of the present disclosure;

FIG. 2 is a use state view illustrating a state in which a secondary battery is inserted into the secondary battery inspection device in FIG. 1 and the secondary battery is pressed;

FIG. 3 is an exploded perspective view illustrating a state in which a pad part and an interleaving sheet are separated from a plate in the secondary battery inspection device according to a second embodiment of the present disclosure;

FIG. 4 to FIG. 7 are plan views illustrating only the pad part for illustrating various shapes of a partial pressing part in the secondary battery inspection device according to the second embodiment of the present disclosure;

FIG. 8 is a plan view schematically illustrating the secondary battery inspection device according to a third embodiment of the present disclosure;

FIG. 9 is a use state view illustrating a state in which a secondary battery is inserted into the secondary battery inspection device in FIG. 8 and the secondary battery is pressed;

FIG. 10 is an enlarged view enlarging part A in FIG. 9;

FIG. 11 is a view illustrating only the secondary battery and a probe in FIG. 10 in an X-axis direction; and

FIG. 12 is a flowchart showing a secondary battery inspection method according to an embodiment of the present disclosure.

### DETAILED DESCRIPTION

The terms used in the present disclosure are used to describe an embodiment, and are not intended to limit the present disclosure. Singular expressions include plural expressions unless the context clearly indicates otherwise.

In adding reference numerals to components throughout the drawings, it is to be noted that like or similar reference numerals designate like or similar components even though the components are illustrated in different drawings.

The drawings may be exaggerated or shown schematically for description of an embodiment. In the present disclosure disclosed herein, the expressions “have”, “may have”, “include” and “comprise”, or “may include” and “may comprise” used herein indicate existence of corresponding features (e.g., elements such as numeric values, functions, operations, or components) but do not exclude presence of additional features.

The terms “one”, “other”, “another”, “first”, “second”, and so on are used to differentiate one constituent element from another constituent element, and these constituent elements should not be limited by these terms.

Hereinafter, an embodiment of the present disclosure will be described in detail with reference to the accompanying drawings.

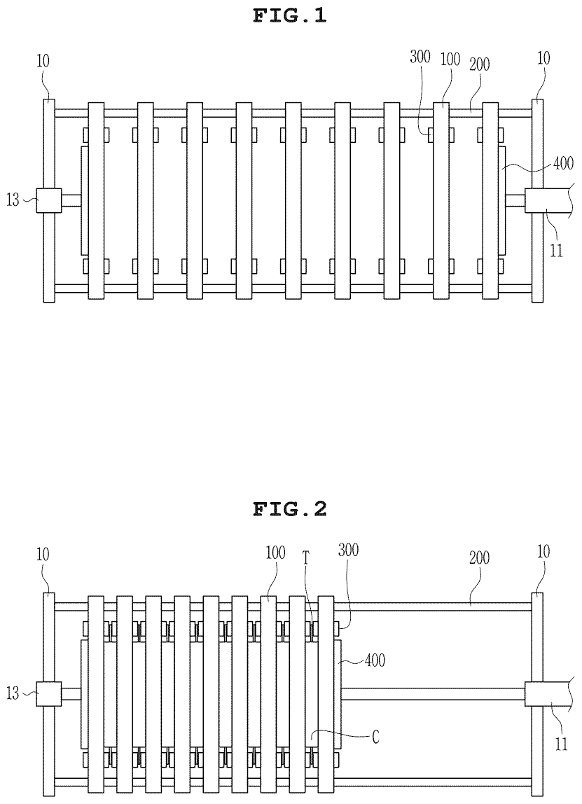

FIG. 1 is a plan view schematically illustrating a secondary battery inspection device according to a first embodiment of the present disclosure, and FIG. 2 is a use state view illustrating a state in which a secondary battery is inserted into the secondary battery inspection device in FIG. 1 and the secondary battery is pressed.

Referring to FIG. 1 and FIG. 2, the secondary battery inspection device according to the first embodiment of the present disclosure may include a plate 100 provided such that the plate 100 is capable of being slidably moved, a movement guide part 200 configured to guide a movement of the plate 100, and a pressing part 400 configured to press one side portion of the plate 100.

The plate 100 may be provided as one plate 100 or a plurality of plates 100. The plurality of plates 100 may be configured such that a secondary battery C is inserted between the plurality of plates 100 disposed to be spaced apart from each other by a predetermined distance and the secondary battery C is pressed. Each of the plates 100 may be a plate body formed of a material which has a high mechanical rigidity and which is not deformed by high heat and high pressure. Each of the plates 100 may be formed of a material with a high mechanical rigidity, such as metal, reinforced plastic, reinforced ceramic, tempered glass, or the like.

The movement guide part 200 may guide the movement of the plate 100. The movement guide part 200 may be provided on a body part 10 supported on the ground surface. The movement guide part 200 may be positioned between a power part 11 and a load cell 13 that are respectively provided on one end portion of the body part 10 and the other end portion of the body part 10, the other end portion of the body part 10 being positioned opposite to the one end portion of the body part 10. Furthermore, the movement guide part 200 may be connected vertically from the one end portion of the body part 10 to the other end portion of the body part 10. In addition, the movement guide part 200 may be provided in a shape such as a plurality of rods, a plurality of bars, and so on, and the plurality of movement guide parts 200 may be provided on opposite sides of the body part 10 such that the movement guide parts 200 are spaced apart from each other. In addition, the plate 100 may be provided such that the plate 100 crosses the body part 10. The plate 100 is capable of being slidably moved along the plurality of movement guide parts 200 while being in a state in which opposite end portions of the plate 100 are penetrated by the plurality of movement guide parts 200.

The load cell 13 may measure a pressure applied to the plate 100. The load cell 13 may be provided on a position opposite to the power part 11 such that the load cell 13 is spaced apart from the power part 11 by a predetermined distance. The load cell 13 may measure the pressure acting on the plate 100 while supporting the plate 100 that is pressed by the pressing part 400.

The pressing part 400 may apply a pressure to the plate 100. The pressing part 400 may be brought into close contact with the plate 100 from the position opposite to the load cell 13 and may push the plate 100 toward the load cell 13. In addition, in the case of the plurality of plates 100, the pressing part 400 may be in close contact with the nearest plate 100 among the plurality of plates 100, and may apply a pressure toward the load cell 13. In addition, the pressing part 400 may be a plate body and so on. The pressing part 400 is connected to the power part 11, and may receive power from the power part 11. The power part 11 may include a power source such as an electric motor and so on. The power part 11 may press the plate 100 by pushing the pressing part 400 toward the load cell 13, or may release the pressure of the plate 100 by pulling the pressing part 400 toward the opposite side of the load cell 13. In addition, the power part 11 may adjust a pressing force applied to the plate 100 by the pressing part 400 according to the pressure measured in the load cell 13.

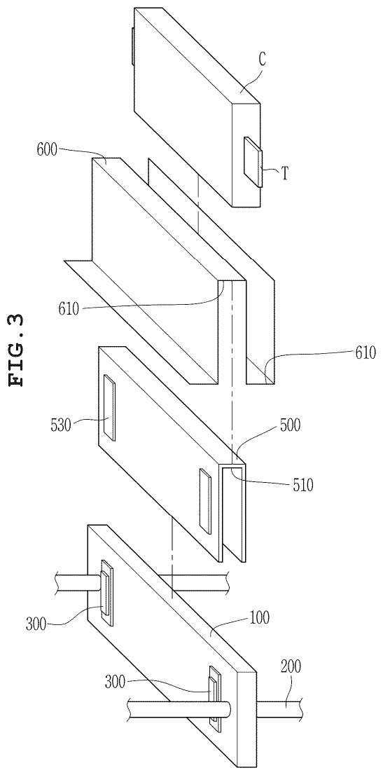

Each probe 300 is provided on opposite side portions of the plate, and may be electrically connected to a tab part of the secondary battery C. Each of the probes 300 may be provided on the both side portions of each of the plurality of the plates 100 such that each of the probes 300 is positioned on positions of each of the plurality of plates 100 facing each other. The probe 300 may be a board-type probe or a clip-type probe. Referring to FIG. 3, the board-type probe 300 may be formed in a substrate shape, and each board-type probe 300 may be provided on both side portions of each of the plurality of plates 100 facing each other. In addition, each of the board-type probes 300 may be electrically in contact with positive electrode and negative electrode tab parts T of the secondary battery C that is inserted between the plurality of plates 100 configured to be pressed by the pressing part 400. In addition, although not illustrated in the drawings, the clip-type probe may be formed in a clip shape, and each clip-type probe may be provided on the both side portions of each of the plurality of plates 100 facing each other. In addition, in a defect inspection of the secondary battery C, an open circuit voltage of the secondary battery C may be measured and a defect of a separator may be inspected by using a short circuit diagnostic device such as an insulation resistance (IR) meter or an open circuit voltage (OCV) meter electrically connected to the probe 300.

As described above, when the pressing part 400 presses the secondary battery C, an internal short circuit occurs at a damaged region of the separator interposed between a positive electrode plate and a negative electrode plate of the secondary battery C, and a leakage current is detected. Therefore, the short circuit diagnostic device may identify a defect as resulting from separator faults when a measured leakage current exceeds a normal range.

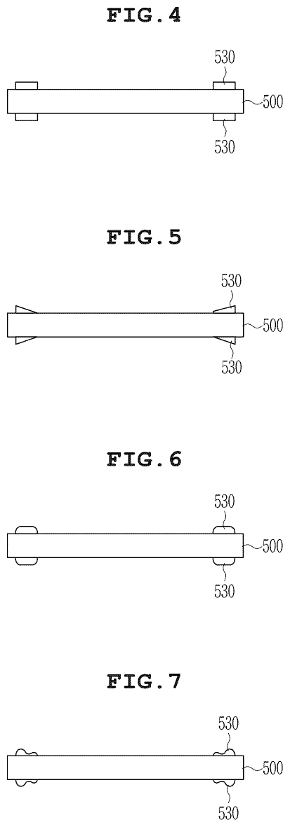

FIG. 3 is an exploded perspective view illustrating a state in which a pad part and an interleaving sheet are separated from the plate in the secondary battery inspection device according to a second embodiment of the present disclosure, and FIG. 4 to FIG. 7 are plan views illustrating only the pad part for illustrating various shapes of a partial pressing part in the secondary battery inspection device according to the second embodiment of the present disclosure.

Referring to FIG. 3 to FIG. 7, the secondary battery inspection device according to the second embodiment of the present disclosure may further include a pad part 500 and an interleaving sheet 600. the plate 100 is configured to press a secondary battery c, and the secondary battery c inspection device further comprises a pad part 500 may be provided between the plate 100 and the secondary battery c. The pad part 500 may be provided on a close contact part between the secondary battery C and the plate 100 pressing the secondary battery C. In addition, when the plurality of plates 100 is provided, the pad part 500 may be provided on a portion of the plurality of plates 100 facing each other. The pad part 500 may relieve an impact to the secondary battery C and may prevent damage to the secondary battery C. The pad part 500 may be manufactured from any one or more materials such as silicone, synthetic resin, and so on. The pad part 500 may include an insertion space part 510 that is bent and the plates 100 is fitted and coupled to the insertion space part 510. The insertion space part 510 may be formed by bending the pad part 500 toward one direction vertically and then bending a portion of the pad part 500 spaced apart from the bent portion by a predetermined distance toward the one direction vertically, which is the same direction. In addition, the plate 100 may be fitted and inserted into the pad part 500 by inserting one end portion of the plate 100 into the insertion space part 510 that is bent. When the plate 100 is coupled to the insertion space part 510, the pad part 500 is positioned between the probe 300 that are provided on the both side portions of the plate 100, so that the probe 300 may be exposed to the outside. In addition, the pad part 500 may include a partial pressing part 530 which has a convex shape and which is provided on both border portions of the pad part 500.

The partial pressing part 530 may be positioned at the both border portions of a portion of the pad part 500 facing the plurality of plates 100. That is, when the separator defect occurs in the secondary battery C such as a pouch-type secondary battery cell, the defect may occur in a portion of the secondary battery C extending to the tab part T in most cases. However, the plate 100 has a flat shape but the secondary battery C such as a pouch-type secondary battery cell has a rounded shape at the portion that extends to the tab part T. Therefore, when the secondary battery C is pressed by the plate 100, the pressing may not be performed properly. Therefore, the partial pressing part 530 may be provided such that the partial pressing part 530 has a convex shape at a position corresponding to a border portion of the secondary battery C where the tab part T extends. In addition, referring to FIG. 4, the partial pressing part 530 may be provided such that the partial pressing part 530 is provided on a position corresponding to the border portion of the secondary battery C where the tab part T extends from the secondary battery C that is inserted between the plurality of plates 100 and the partial pressing part 530 has a shape which is vertically convex and which has a flat-shaped portion at a region where the partial pressing part 530 is brought into contact with the secondary battery C. In addition, when the secondary battery C is pressed by the plate 100, the border portion of the secondary battery C where the tab part T of the secondary battery C extends may be partially pressed by the partial pressing part 530. Then, the short diagnostic device may detect an open circuit voltage generated by partially pressing the secondary battery C in which the separator is damaged. In addition, in order for the partial pressing part 530 to be brought into close contact with the border portion of the secondary battery C where the tab part T extends, the partial pressing part 530 may have an inclined shape as illustrated in FIG. 5, may have a rounded shaped as illustrated FIG. 6, or may have a wavy shape as illustrated in FIG. 7. As the partial pressing part 530 is formed such that the contact surface of the partial pressing part 530 with the secondary battery C has a shape corresponding to the secondary battery C, a missing contact may be prevented when the secondary battery C is pressed, and an open circuit voltage may be accurately detected.

The interleaving sheet 600 may be provided between the secondary battery C and the pad part 500, and may be a sheet having insulation and flame retardant properties such as a sheet woven with materials such as ceramic fibers and aramid. The interleaving sheet 600 may surround the pad part 500 and the secondary battery C may be seated in the interleaving sheet 600. The interleaving sheet 600 is provided with a plurality of interleaving bending parts 610 continuously bent, the pad part 500 may be fitted and coupled to any one of the interleaving bending part 610, and the secondary battery C may be seated in the other interleaving bending part 610 that is bent in a direction opposite to one interleaving bending part 610.

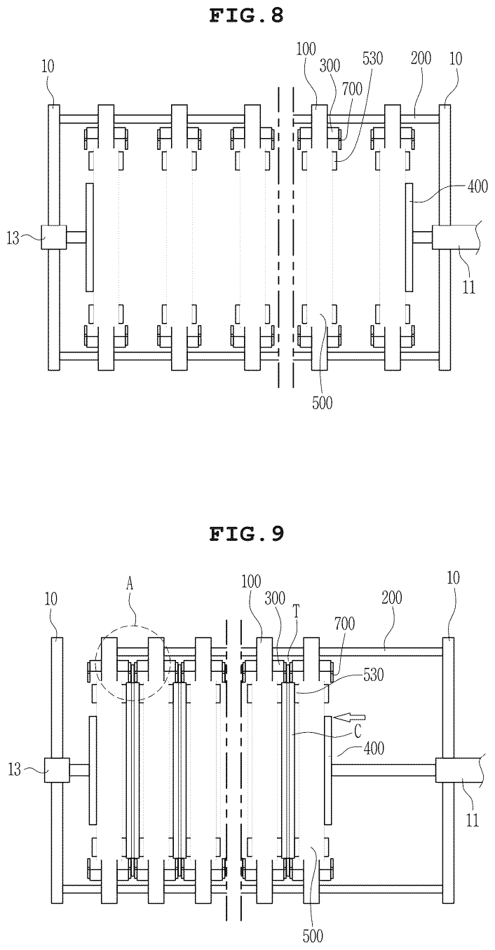

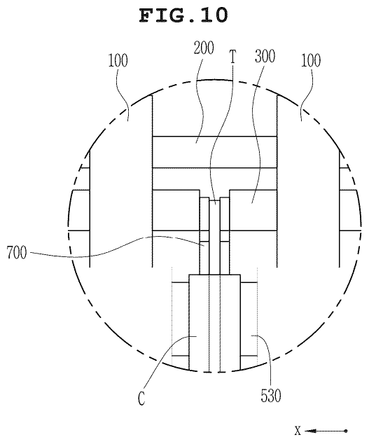

FIG. 8 is a plan view schematically illustrating the secondary battery inspection device according to a third embodiment of the present disclosure, FIG. 9 is a use state view illustrating a state in which the secondary battery is inserted into the secondary battery inspection device in FIG. 8 and the secondary battery is pressed, FIG. 10 is an enlarged view enlarging part A in FIG. 9, and FIG. 11 is a view illustrating only the secondary battery and the probe in FIG. 10 in an X-axis direction.

Referring to FIG. 8 to FIG. 11, the secondary battery inspection device according to the third embodiment of the present disclosure may further include an electrode guide part 700. The electrode guide part 700 may guide the position of the secondary battery C. The electrode guide part 700 is provided on a lower portion of the probe 300, and may guide the secondary battery C to maintain the secondary battery C in a correct position while supporting the secondary battery C from the lower portion of the probe 300, the secondary battery C being in close contact with the plate 100. The electrode guide part 700 may include a guide block 710 and a support block 730. The guide block 710 may be fixed to the lower portion (ground side) of the probe 300, and may extend from the lower portion of the probe 300 toward the secondary battery C. The support block 730 may extend vertically upward (opposite side of the ground side) from an end portion of the guide block 710. The electrode guide part 700 is provided on the probe 300 that is provided on the both sides of the plate 100, and removes a gap between the probe 300 and the secondary battery C from both sides of the secondary battery C, thereby being capable of fixing the position of the secondary battery C.

Hereinafter, a secondary battery inspection method of the present disclosure will be described in detail with reference to the following drawings.

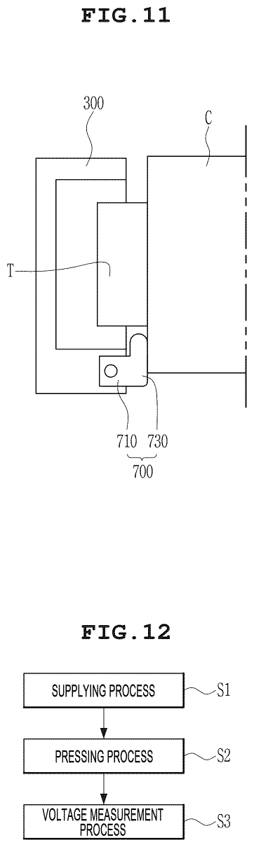

FIG. 12 is a flowchart showing the secondary battery inspection method according to an embodiment of the present disclosure.

As illustrated in FIG. 12, the secondary battery inspection method according to an embodiment of the present disclosure may include a supplying process S1, a pressing process S2, and a voltage measurement process S3.

Referring to FIG. 1 to FIG. 12, the supply process S1 may be a process of supplying the secondary battery C. The supply process S1 may be a process in which the secondary battery C in which a secondary battery assembly process that is a previous process is finished is inserted between the plates 100 of the secondary battery inspection device of the present disclosure.

The pressing process S2 may be a process of pressing the secondary battery C. The pressing process S2 may be a process in which the secondary battery C supplied in the supplying process S1 is inserted into the secondary battery inspection device of the present disclosure and then the secondary battery C is pressed by using the secondary battery inspection device of the present disclosure. In addition, in the pressing process S2, the secondary battery C may be partially pressed by using the secondary battery inspection device of the present disclosure. In the pressing process S2, the secondary battery inspection device of the present disclosure may partially press the extension portion of the tab part T in the secondary battery C.

The voltage measurement process S3 may be a process of measuring a voltage in the secondary battery C. The voltage measurement process S3 may be a process of measuring an open circuit voltage of the secondary battery C while the secondary battery C is pressed by the secondary battery inspection device of the present disclosure in the pressing process S2. In the voltage measurement process S3, an open circuit voltage of the secondary battery C may be measured by using a short circuit diagnostic device such as an insulation resistance (IR) meter or an open circuit voltage (OCV) meter, the secondary battery C being pressed. After the voltage measurement process S3 is completed, the pressure applied to the secondary battery C is released, the secondary battery C in which the open circuit voltage is detected is classified as a defective secondary battery C, and then the secondary battery C in which the open circuit voltage is not detected may proceed to a subsequent process.

The present disclosure has been described in detail through specific embodiments. The embodiment is proposed to more concretely describe the present disclosure. However, the embodiment is only given for illustrating the present disclosure and those skilled in the related art will obviously understand that various alterations and modifications are possible within the scope and spirit of the present disclosure. Such alterations and modifications are duly included in the appended claims.

What is claimed is:

1. A secondary battery inspection device comprising:
a plate provided such that the plate is capable of being slidably moved;
a movement guide part guiding a movement of the plate; and
a pressing part configured to press one side portion of the plate.

2. The secondary battery inspection device of claim 1, wherein the plate is configured to press a secondary battery, and the secondary battery inspection device further comprises a pad part provided between the plate and the secondary battery.

3. The secondary battery inspection device of claim 2, wherein the pad part comprises a partial pressing part which has a convex shape and which is provided on both border portions of the pad part.

4. The secondary battery inspection device of claim 2, wherein the pad part comprises a partial pressing part which has a convex shape and which is provided on a position corresponding to a border portion of the secondary battery where a tab part extends.

5. The secondary battery inspection device of claim 4, wherein the partial pressing part is formed in a flat shape, a rounded shape, or a wavy shape so that the partial pressing part is capable of being in close contact with the border portion of the secondary battery.

6. The secondary battery inspection device of claim 2, wherein the pad part is provided with an insertion space part that is bent, and the plate is fitted and coupled to the insertion space part.

7. The secondary battery inspection device of claim 2, further comprising:
an interleaving sheet which is configured to surround the pad part and in which the secondary battery is seated.

8. The secondary battery inspection device of claim 7, wherein the interleaving sheet is provided with a plurality of interleaving bending parts continuously bent, the pad part is fitted and coupled to any one interleaving bending part, and the secondary battery is seated in the other interleaving bending part.

9. The secondary battery inspection device of claim 2, further comprising:
a probe provided on opposite side portions of the plate and electrically connected to a tab part of the secondary battery.

10. The secondary battery inspection device of claim 9, further comprising:
an electrode guide part guiding a position of the secondary battery.

11. The secondary battery inspection device of claim 10, wherein the electrode guide part is provided on a lower portion of the probe, and supports the secondary battery from the lower portion of the probe.

12. The secondary battery inspection device of claim 11, wherein the electrode guide part comprises:
a guide block which is fixed to the lower portion of the probe and which extends vertically from the lower portion of the probe toward the secondary battery; and
a support block that extends vertically upward from an end portion of the guide block.

13. A secondary battery inspection method comprising:
a supplying process in which a secondary battery is supplied;
a pressing process in which the secondary battery is pressed; and
a voltage measurement process in which a voltage in the secondary battery is measured.

14. The secondary battery inspection method of claim 13, wherein, in the pressing process, the secondary battery is partially pressed.

15. The secondary battery inspection method of claim 14, wherein, in the pressing process, an extension portion of a tab part in the secondary battery is partially pressed.
